(19) United States
(12) Patent Application Publication
(10) Pub. No.: US 2026/0352191 A1
(43) Pub. Date: Nov. 5, 2026

(54) CLOCK DIVIDER CIRCUIT AND STORAGE DEVICE

(71) Applicant: Samsung Electronics Co., Ltd., Suwon-si (KR)

(72) Inventors: Cheol Min Ahn, Suwon-si (KR); Hyo Jun Byun, Suwon-si (KR); Ga Ram Choi, Suwon-si (KR); Jae Woo Lee, Suwon-si (KR); Ki Han Kim, Suwon-si (KR); Dae Sik Moon, Suwon-si (KR)

(21) Appl. No.: 19/394,397

(22) Filed: Nov. 19, 2025

(30) Foreign Application Priority Data
May 2, 2025 (KR) 10-2025-0058287

(51) Int. Cl. H03K 3/037; G11C 11/4076; H03K 5/00

(52) U.S. Cl. CPC H03K 3/0372; G11C 11/4076; H03K 5/00006

(57) ABSTRACT

A clock divider circuit includes first to fourth tri-state inverters connected in series. The first to fourth tri-state inverters are configured to divide an input clock into multiple output clocks, and a latch configured to provide the first tri-state inverter output to the second tri-state inverter input, and to provide the third tri-state inverter output the fourth tri-state inverter input. The first tri-state inverter includes a first inverter connected between input and output terminals of the first tri-state inverter, and a first active transistor configured to provide a driving voltage to the first inverter, a second active transistor configured to provide a ground voltage to the first inverter, and a discharge transistor connected to the first inverter and configured to remove accumulated charges generated by at least one of the first active transistor and the second active transistor.

### CROSS-REFERENCE TO RELATED APPLICATION

This application claims priority from Korean Patent Application No.10-2025-0058287 filed on May 2, 2025, in the Korean Intellectual Property Office, and all the benefits accruing therefrom under 35 U.S.C. 119, the contents of which in its entirety are herein incorporated by reference.

### BACKGROUND

A storage device including an input/output circuit receives and processes a data signal, a command/address signal, a chip select signal, and the like from a host. In addition, some storage devices and memory devices receive a clock from a host and process a signal based on the received clock. For example, the storage device may receive a data clock and a data signal from the host, and may sample data of the data signal based on the data clock. In this regard, the clock divider circuit of the storage device may output the clock received from the host as a plurality of clocks. In order to operate a read operation at a high speed, the storage device may output and use the received clock as the plurality of clocks.

### SUMMARY

For a storage device to operate faster at lower power, a clock divider circuit may operate faster at lower power. However, when the operation speed of the clock divider circuit is increased, a glitch problem may occur. In the present disclosure, the glitch includes a charge sharing phenomenon in which charges are accumulated at a node to which circuit elements are connected and the accumulated charges therein are shared with another node in a clock divider circuit. When the accumulated charge is shared with the output node of the clock divider circuit, the voltage of the output node increases or decreases, which may cause an error in the operation of the storage device.

The present disclosure relates to a clock divider circuit and a storage device including the same.

A technical purpose to be achieved by the present disclosure is to provide a clock divider circuit with improved reliability.

Another technical purpose to be achieved by the present disclosure is to provide a storage device including the clock divider circuit.

The technical purposes of the present disclosure are not limited to the above-mentioned technical purposes, and other technical purposes not mentioned may be clearly understood by a person skilled in the art of the present disclosure from the following description.

According to an aspect of the present disclosure, there is provided a clock divider circuit comprising first to fourth tri-state inverters connected in series with each other to constitute a closed circuit, wherein each of the first to fourth tri-state inverters is configured to be controlled based on an input clock to divide the input clock into a plurality of output clocks, and a latch configured to latch an output of the first tri-state inverter and provide a latched signal to an input of the second tri-state inverter, and to latch an output of the third tri-state inverter and provide a latched signal to an input of the fourth tri-state inverter, wherein the first tri-state inverter includes a first inverter connected to an input terminal and an output terminal of the first tri-state inverter, and a first active transistor configured to be gated based on the input clock to provide a driving voltage to the first inverter, a second active transistor configured to be gated based on the input clock to provide a ground voltage to the first inverter, and a discharge transistor connected to the first inverter and configured to remove accumulated charges generated by at least one of the first active transistor and the second active transistor.

According to an aspect of the present disclosure, there is provided A clock divider circuit comprising first to fourth tri-state inverters connected in series with each other to constitute a closed circuit, wherein each of the first to fourth tri-state inverters is configured to be controlled based on a first input clock and a second input clock to divide the first input clock and the second input clock into a plurality of output clocks, wherein logic levels of the first and second input clocks are inverted relative to each other, a first latch having a first input connected to an output of the first tri-state inverter and an input of the fourth tri-state inverter, and having a second input connected to an output of the third tri-state inverter and an input of the second tri-state inverter, and a second latch having a third input connected to an output of the fourth tri-state inverter and an input of the third tri-state inverter, and having a fourth input connected to an output of the second tri-state inverter and an input of the first tri-state inverter, wherein the first tri-state inverter includes first and second transistors configured to invert an input of the first tri-state inverter and output the inverted input, a first active transistor configured to provide a driving voltage to the first transistor based on the first input clock, a second active transistor configured to provide a ground voltage to the second transistor based on the second input clock, and a first discharge transistor connected to the first transistor and the first active transistor and configured to provide the ground voltage to the first transistor and the first active transistor based on the second input clock.

According to an aspect of the present disclosure, there is provided a storage system comprising a memory device, a storage controller configured to control the memory device, and an input/output circuit configured to transmit an external input to the memory device and the storage controller, wherein the input/output circuit includes a clock divider circuit configured to divide an input clock into a plurality of output clocks, wherein the clock divider circuit includes first to fourth tri-state inverters connected in series with each other to constitute a closed circuit, wherein each of the first to fourth tri-state inverters is configured to be controlled based on an input clock to divide the input clock into a plurality of output clocks, and a latch configured to latch an output of the first tri-state inverter and provide a latched signal to an input of the second tri-state inverter, and to latch an output of the third tri-state inverter and provide a latched signal to an input of the fourth tri-state inverter, wherein the first tri-state inverter includes a first inverter connected to an input terminal and an output terminal of the first tri-state inverter, and a first active transistor configured to be gated based on the input clock to provide a driving voltage to the first inverter, a second active transistor configured to be gated based on the input clock to provide a ground voltage to the first inverter, and a discharge transistor connected to the first inverter and configured to remove accumulated charges generated by at least one of the first active transistor and the second active transistor.

Specific details of other implementations are included in the detailed description and drawings.

### BRIEF DESCRIPTION OF DRAWINGS

The above and other aspects and features of the present disclosure will become more apparent by illustrating in detail implementations thereof with reference to the attached drawings, in which:

FIG. 1 is a block diagram for illustrating a data transmission/reception system according to some implementations.

FIG. 2 is a block diagram illustrating the storage device 30 of FIG. 1.

FIG. 3 is a block diagram illustrating the input/output circuit 100 according to some implementations.

FIGS. 4 and 5 are circuit diagrams illustrating the clock divider circuit 120 according to some implementations.

FIG. 6 is a timing diagram for illustrating an operation of a circuit according to FIGS. 4 and 5.

FIGS. 7 and 8 are circuit diagrams for illustrating an operation of a circuit according to FIGS. 4 and 5.

FIG. 9 is a signal analysis diagram for illustrating an effect according to the use of the circuit illustrated in FIGS. 4 and 5.

FIG. 10 is a circuit diagram illustrating a clock divider circuit according to some implementations.

FIG. 11 is a signal analysis diagram for illustrating an effect of using the circuit illustrated in FIG. 10.

FIG. 12 is a circuit diagram illustrating a clock divider circuit according to some implementations.

FIG. 13 is a signal analysis diagram for illustrating an effect of using the circuit illustrated in FIG. 12.

FIG. 14 is a circuit diagram illustrating a clock divider circuit according to some implementations.

FIG. 15 is a circuit diagram illustrating a clock divider circuit according to some implementations.

FIG. 16 is a timing diagram for illustrating an effect of using the circuit illustrated in FIG. 15.

FIG. 17 is a circuit diagram illustrating a clock divider circuit according to some implementations.

FIG. 18 is a circuit diagram illustrating a tri-state inverter of a clock divider circuit according to some implementations.

FIG. 19 is a circuit diagram illustrating a tri-state inverter of a clock divider circuit according to some implementations.

FIG. 20 is a circuit diagram illustrating a tri-state inverter of a clock divider circuit according to some implementations.

FIG. 21 is a signal analysis diagram for illustrating an effect of using the circuit illustrated in FIG. 20.

FIG. 22 is a block diagram for illustrating an electronic device including a storage device to which a clock divider circuit according to some implementations is applied.

### DETAILED DESCRIPTIONS

Hereinafter, implementations according to the technical idea of the present disclosure will be described with reference to the accompanying drawings.

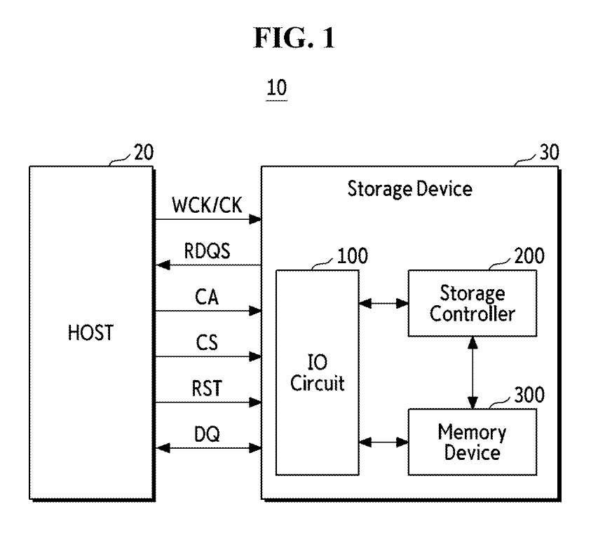

FIG. 1 is a block diagram for illustrating a data transmission/reception system according to some implementations.

Referring to FIG. 1, a transmission/reception system 10 (e.g., a memory system) may include a host 20 and a storage device 30. In some implementations, in order to exchange data with each other, the host 20 and the storage device 30 may exchange an external clock signal WCK/CK, a read data strobe signal RDQS, a command/address transfer signal CA, a chip select signal CS, a reset signal RST, and a data signal DQ with each other.

The external clock signal WCK/CK may be a signal transmitted from the host 20 to the storage device 30. The external clock signal WCK/CK may include a data clock Write Clock (WCK) and a system clock CK. The read data strobe signal RDQS may be a signal used as a timing reference for the host to receive data during a read operation of the storage device 30. The command/address transmission signal CA may be a signal for transmitting command and address information. The chip select signal CS may be a signal for determining whether to select a memory chip in the storage device 30. The reset signal RST may be a signal for initializing the clock division signal in the memory device. The data signal DQ may be a signal including write data and/or read data. In the present disclosure, the data signal DQ may be referred to as 'data DQ'.

Although only the external clock signal WCK/CK, the read data strobe signal RDQS, the command/address transfer signal CA, the chip select signal CS, the reset signal RST, and the data signal DQ have been described with reference to FIG. 1, the signals exchanged between the host 20 and the storage device 30 are not limited thereto. In addition, it has been described that the data clock WCK and the system clock CK are included in the external clock signal WCK/CK. However, the present disclosure is not limited thereto.

In some implementations, the storage device 30 may include an input/output circuit 100, a storage controller 200, and a memory device 300. The storage device 30 may include media for storing data therein in response to a request from the host 20. For example, the storage device 30 may include volatile memories (VM) such as a Dynamic Random Access Memory (DRAM), a Double Data Rate 4 (DDR4) SDRAM(Synchronous DRAM), DDR5 SDRAM, LPDDR4 (Low Power DDR4) SDRAM, or a LPDDR5 SDRAM, etc. However, implementations according to the technical idea of the present disclosure are not limited thereto, and the storage device 30 may include a nonvolatile memory. For example, the storage device 30 may include vertical-NAND flash memory (V-NAND) of a 2-Dimensional (2-D) structure or a 3-Dimensional (3-D) structure. The storage device 30 may include other types of non-volatile memories (NVM) such as a NAND flash memory, a NOR flash memory, a solid state drive (SSD), a phase-change random access memory (PRAM), and/or a resistive random access memory (RRAM).

The input/output circuit 100 may be a communication circuit that exchanges data with the host. The input/output circuit 100 may be composed of a physical layer (PHY) to transmit and receive electrical signals. The storage controller 200 may be a circuit that controls the input/output circuit 100 and the memory device 300. The memory device 300 may be composed of a plurality of memory arrays to actually physically store data therein.

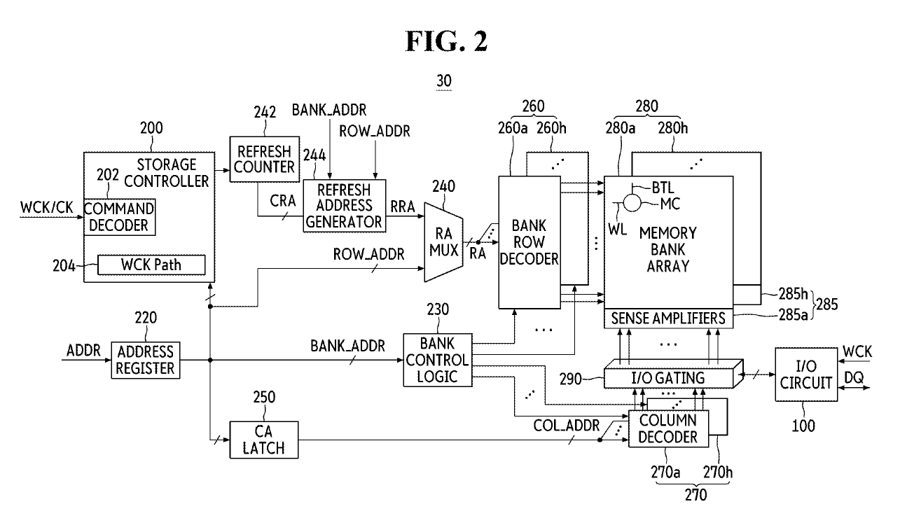

FIG. 2 is a block diagram illustrating the storage device 30 of FIG. 1.

Referring to FIG. 2, the storage device 30 may include the storage controller 200, an address register 220, a bank control logic circuit 230, a row address multiplexer 240, a refresh counter 242, a refresh address generator 244, a column address latch 250, a row decoder 260, a column decoder 270, a memory cell array 280, a sense amplifier unit 285, an input/output gating circuit 290, and the input/output circuit 100.

In some implementations, the memory device 300 may include the memory cell array 280.

The memory cell array 280 may include a plurality of memory bank arrays 280a to 280h. FIG. 2 illustrates an example in which the memory cell array 280 includes eight memory bank arrays 280a to 280h. However, implementations of the present disclosure are not limited thereto.

Each of the plurality of memory bank arrays 280a to 280h may include a plurality of word lines WL, a plurality of bit lines BL, and a plurality of memory cells MC respectively disposed at intersections at which the word lines WL and the bit lines BL intersect each other.

The row address multiplexer 240 may include a plurality of bank row decoders 260a to 260h respectively connected to the plurality of memory bank arrays 280a to 280h. The column decoder 270 may include a plurality of column decoders 270a to 270h respectively connected to the plurality of memory bank arrays 280a to 280h. The sense amplifier unit 285 may include a plurality of sense amplifiers 285a to 285h respectively connected to the plurality of memory bank arrays 280a to 280h.

The address register 220 may receive an address ADDR including a bank address BANK_ADDR, a row address ROW_ADDR, and a column address COL_ADDR from the storage controller 200 of FIG. 1. The address register 220 may provide the received bank address BANK_ADDR to the bank control logic circuit 230, may provide the received row address ROW_ADDR to the row address multiplexer 2 40, and may provide the received column address COL_ADDR to the column address latch 250.

The bank control logic circuit 230 may generate bank control signals in response to the bank address BANK_ADDR. In response to the bank control signals, a bank row decoder corresponding to the bank address BANK_ADDR among the plurality of bank row decoders 260a to 260h may be activated, and a column decoder corresponding to the bank address BANK_ADDR among the plurality of column decoders 270a to 270h may be activated.

The refresh counter 242 may sequentially output a counting row address CRA under the control of the storage controller 200. For example, the storage controller 200 may generate a refresh count signal REF_CNT in response to a normal refresh command. The refresh counter 242 may perform a counting operation in response to the refresh count signal and output the counting row address CRA. That is, the refresh counter 242 may output a refresh address REF_ADDR for performing a normal refresh operation.

The refresh address generator 244 may receive the bank address BANK_ADDR and the row address ROW_ADDR. The refresh address generator 244 may count a value as a number of times by which each of the bank address BANK_ADDR and the row address ROW_ADDR is activated based on each of the bank address BANK_ADDR and the row address ROW_ADDR. The refresh address generator 244 may generate a row address RADD corresponding to a word line WL activated a predetermined number of times or greater based on the counted value, or a row address RADD corresponding to a word line WL adjacent to the word line WL as a hammer address HADD. That is, the refresh address generator 244 may output a refresh address for performing a target row refresh operation.

The refresh address generator 244 may output one of the counting row address CRA and the hammer address as a refresh row address RRA.

The refresh counter 242 and the refresh address generator 244 may be implemented as separate components as illustrated, or the refresh counter 242 and the refresh address generator 244 may be implemented as one component. In addition, the refresh counter 242 and the refresh address generator 244 may be implemented so as to be included in the storage controller 200.

The row address multiplexer 240 may receive the row address ROW_ADDR from the address register 220 and may receive the refresh row address RRA from the refresh address generator 244. The row address multiplexer 240 may selectively output the row address ROW_ADDR or the refresh row address RRA as a row address RA. The row address RA output from the row address multiplexer 240 may be applied to each of the plurality of bank row decoders 260a to 260h.

A bank row decoder activated by the bank control logic circuit 230 among the plurality of bank row decoders 260a to 260h may decode the row address RA output from the row address multiplexer 240 to activate a word line corresponding to the row address. For example, the activated bank row decoder may apply a word line driving voltage to a word line corresponding to the row address.

The column address latch 250 may receive the column address COL_ADDR from the address register 220 and temporarily store therein the received column address COL_ADDR. The column address latch 250 may gradually increase the received column address COL_ADDR in a burst mode. The column address latch 250 may apply the temporarily stored or gradually increased column address COL_ADDR to each of the plurality of column decoders 270a to 270h.

A bank column decoder activated by the bank control logic circuit 230 among the plurality of column decoders 270a to 270h may activate a sense amplifier corresponding to the bank address BANK_ADDR and the column address COL_ADDR via a corresponding input/output gating circuit 290.

The input/output gating circuit 290 may include circuits for gating input/output data, an input data mask logic, read data latches for storing therein data output from the plurality of memory bank arrays 280a to 280h, and write drivers for writing data to the plurality of memory bank arrays 280a to 280h.

The data DQ to be read from one bank array among the plurality of memory bank arrays 280a to 280h may be sensed by one of the sense amplifiers 285a to 285h corresponding to the one bank array and may be stored in the read data latches. The data DQ stored in the read data latches may be provided to the host 20 in a synchronized manner with the data clock WCK via the input/output circuit 100.

The data DQ to be written to one bank array among the plurality of memory bank arrays 280a to 280h may be provided to the input/output gating circuit 290 in a synchronized manner with the data clock WCK via the input/output circuit 100. The input/output gating circuit 290 may write the data to the one bank array via the write drivers.

The storage controller 200 may control an operation of the storage device 30. For example, the storage controller 200 may generate control signals such that the storage device 30 performs a write operation or a read operation. The storage controller 200 may include a command decoder 202 that decodes a command CMD received from the host 20.

According to some implementations, the storage controller 200 may further include a data clock path a WCK Path 204. Although FIG. 2 illustrates that the data clock path 204 is included in the storage controller 200, the data clock path 204 may be separate from the storage controller 200 according to some implementations of the disclosure. The storage controller 200 may receive the system clock CK and the data clock WCK from the host 20. The system clock CK may be a clock for processing the command CMD and the address ADDR. The data clock WCK may be a clock for processing the data DATA. As the data clock WCK passes through the data clock path 204 of the storage device 30, a delay may occur in the data clock WCK. Accordingly, the data clock path 204 may include a compensation circuit capable of compensating for the delay of the data clock WCK in which the delay has occurred, thereby reducing the influence of the delay.

The memory cell MC may be, for example, a DRAM memory cell. The memory cell MC may be connected to one word line WL and one bit line BL. The memory cell MC may store charges in a cell capacitor. Since a leakage current occurs in the memory cell MC due to the structure of the memory cell MC, data stored in the cell capacitor may be lost. Accordingly, the storage device 200 may perform a refresh operation of recharging the data in the memory cell MC, in order to prevent the data stored in the memory cell MC from being changed by the leakage current.

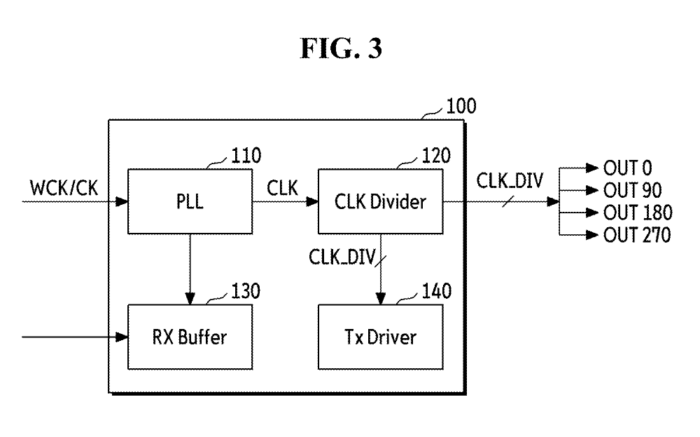

FIG. 3 is a block diagram illustrating the input/output circuit 100 according to some implementations.

Referring to FIG. 3, the input/output circuit 100 may include a phase locked loop (PLL) 110, a clock (CLK) divider 120, a receive (RX) buffer 130, and a transmit (TX) driver 140. The PLL 110 may transform the external clock signal WCK/CK into a stabilized clock signal and output the stabilized clock signal. The clock signal output from the PLL 110 may be used as a reference clock in an internal circuit in the storage device. The PLL 110 may output a differential signal and provide the differential signal as an input to the clock divider 120. The clock divider 120 may divide the input clock signal into a plurality of clock signals CLK_DIV. In some implementations, the clock divider 120 may divide one clock signal into 2, 4, or 8 clock signals. In some other implementations, the clock divider 120 may divide a differential signal into four or eight clock signals. In the present disclosure, an example in which the clock divider circuit 120 divides the differential signal into four clock signals CLK_DIV (OUT0, OUT90, OUT180, and OUT270) will be described. The plurality of divided clock signals CLK_DIV may be clocks used in the storage device 30. The RX buffer 130 may convert a signal (e.g., a data signal DQ, a read data strobe signal RDQS, etc.) received from an external source and transmit the converted signal to another circuit. The TX driver 140 may transmit the data based on the plurality of clock signals CLK_DIV.

In the present disclosure, an example in which the clock signal input to the clock divider 120 is based on the signal output from the PLL 110 is described. However, it should be understood that both a configuration that the clock divider 120 divides the clock signal generated in the storage device 30, and a configuration that the clock driver 120 directly receives the external clock signal are included in the present disclosure.

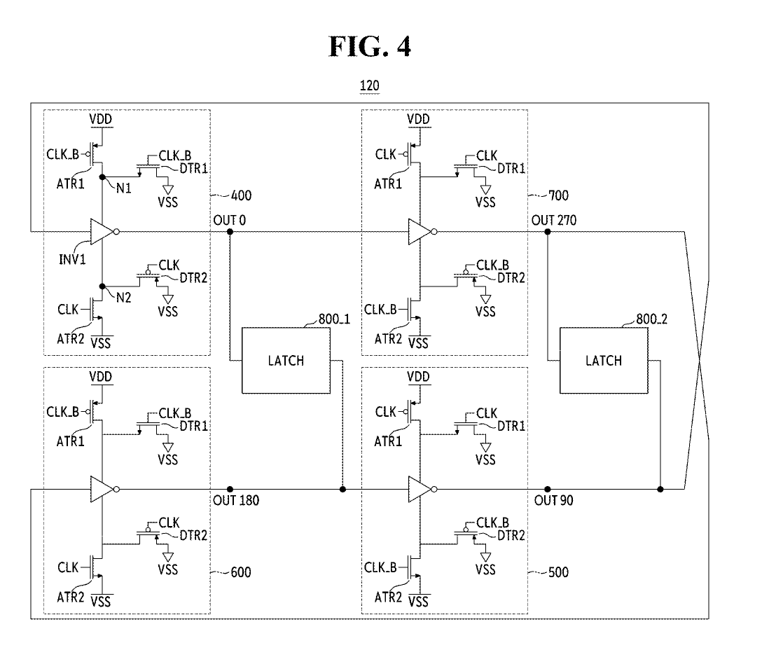

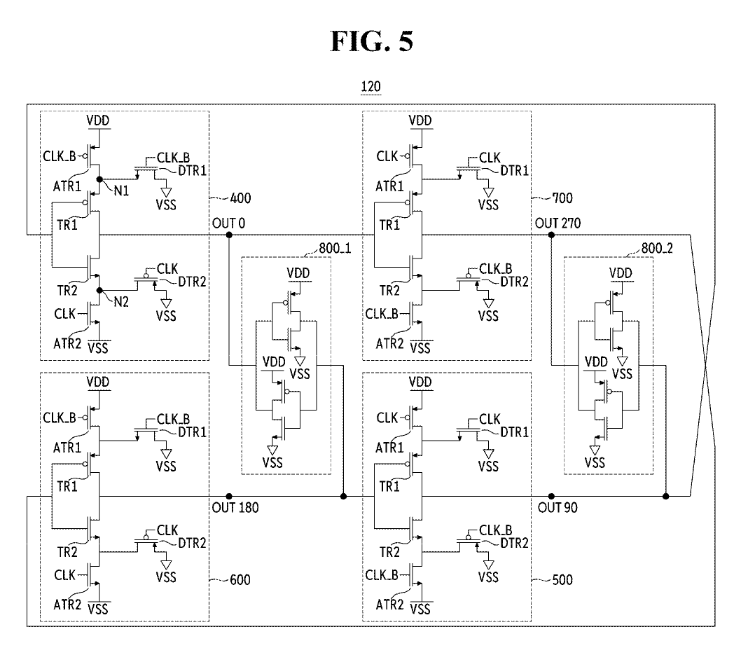

FIGS. 4 and 5 are circuit diagrams illustrating the clock divider circuit 120 according to some implementations.

In some implementations, the clock divider 120 of FIG. 3 may be implemented as, for example, the clock divider circuit 120 illustrated in FIGS. 4 and 5.

Referring to FIG. 4, the clock divider circuit 120 may include first to fourth tri-state inverters 400, 500, 600, and 700, a first latch 800_1, and a second latch 800_2.

The first to fourth tri-state inverters 400, 500, 600, and 700 may be connected in series with each other. In some implementations, an output of the first tri-state inverter 400 may be connected to an input of the fourth tri-state inverter 700, an output of the fourth tri-state inverter 700 may be connected to an input of the third tri-state inverter 600, an output of the third tri-state inverter 600 may be connected to an input of the second tri-state inverter 500, and an output of the second tri-state inverter 500 may be connected to an input of the first tri-state inverter 400. In this manner, the first to fourth tri-state inverters 400, 500, 600, and 700 form a closed loop or closed circuit. Generally, the tri-state inverters can form a closed loop or closed circuit by being connected in series and having the output of the last transistor in the series connected with the input of the first transistor in the series.

The first latch 800_1 may invert a logic level of a signal input to a first input and provide a signal of the inverted logic level to a second input, and may invert a logic level of the signal input to the second input and provide a signal of the inverted logic level to the first input. The first latch 800_1 may be an element that stores therein the logic values of the first input and the second input. In some implementations, the first input of the first latch 800_1 may be connected to the output of the first tri-state inverter 400, and the second input may be connected to the input of the second tri-state inverter 500.

The second latch 800_2 may invert a logic level of a signal input to a third input and provide a signal of the inverted logic level to a fourth input, and may invert the logic level of the signal input to the fourth input and provide a signal of the inverted logic level to the third input. The second latch 800_2 may be an element that stores therein logical values of the third input and the fourth input. In some implementations, the third input of the second latch 800_2 may be connected to the output of the fourth tri-state inverter 700, and the fourth input may be connected to the input of the third tri-state inverter 600.

The first output OUT0 output from the first tri-state inverter 400, the second output OUT90 output from the second tri-state inverter 500, the third output OUT180 output from the third tri-state inverter 600, and the fourth output OUT270 output from the fourth tri-state inverter 700 may be clock outputs of which phases are different by 90 degrees from each other.

In some implementations, the first to fourth tri-state inverters 400, 500, 600, and 700 may have the same element configuration. Hereinafter, the first tri-state inverter 400 will be described by way of example.

Referring to FIGS. 4 and 5 the first tri-state inverter 400 may include a first inverter INV1, a first active transistor ATR1, a second active transistor ATR2, a first discharge transistor DTR1, and a second discharge transistor DTR2.

The first tri-state inverter 400 may be controlled, for example, based on a differential signal. The differential signal may include a first input clock CLK and a second input clock CLK_B configured to having an inverted logic level of the logic level of the first input clock CLK.

The first inverter INV1 may include, for example, a first transistor TR1 and a second transistor TR2. The first inverter INV1 may receive a driving voltage VDD via the first active transistor ATR1 and may receive a ground voltage VSS via the second active transistor ATR2.

One end of the first active transistor ATR1 may be connected to a driving voltage VDD node, and one end thereof may be connected to the first transistor TR1. The first active transistor ATR1 may be gated based on the second input clock CLK_B to provide the driving voltage VDD to the first inverter INV1.

One end of the second active transistor ATR2 may be connected to a ground voltage VSS node, and one end thereof may be connected to the second transistor TR2. The second active transistor ATR2 may be gated based on the first input clock CLK to provide the ground voltage VSS to the first inverter INV1.

One end of the first discharge transistor DTR1 may be connected to a first node N1 to which the first inverter INV1 and the first active transistor ATR1 are connected, and the other end thereof may be connected to the ground voltage VSS node. The first discharge transistor DTR1 may be gated based on the second input clock CLK_B to provide the ground voltage VSS to the first node N1.

One end of the second discharge transistor DTR2 may be connected to a second node N2 to which the first inverter INV1 and the second active transistor ATR2 are connected, and the other end thereof may be connected to the ground voltage VSS node. The second discharge transistor DTR2 may be gated based on the first input clock CLK to provide the ground voltage VSS to the second node N2.

In some implementations, the first discharge transistor DTR1 and the second discharge transistor DTR2 may remove accumulated charges of the first node N1 and the second node N2, respectively. The first discharge transistor DTR1 may be activated based on an inverted logic level of a logic level based on which the first active transistor ATR1 is activated, thereby removing the accumulated charge of the first node N1. For example, the first active transistor ATR1 is activated when the second input clock CLK_B is at a logic low level (hereinafter, LOW). In this case, the first discharge transistor DTR1 may be activated when the second input clock CLK_B is at a logic high level HIGH, thereby removing the accumulated charge of the first node N1.

The second discharge transistor DTR2 may be activated based on an inverted logic level of a logic level based on which the second active transistor ATR2 is activated, thereby removing the accumulated charge of the second node N2. For example, the second active transistor ATR2 is activated when the first input clock CLK is at the logic high level HIGH. In this case, the second discharge transistor DTR2 may be activated when the first input clock CLK is at the logic low level LOW, thereby removing the accumulated charge of the second node N2.

In some implementations, each of the first latch 800_1 and the second latch 800_2 may include inverter elements. Each of the first latch 800_1 and the second latch 800_2 may have a structure in which an output of one inverter is connected to an input of the other inverter, and an output of the other inverter is connected to an input of one inverter. Each of the inverters of each of the first latch 800_1 and the second latch 800_2 may be an inverter including transistors.

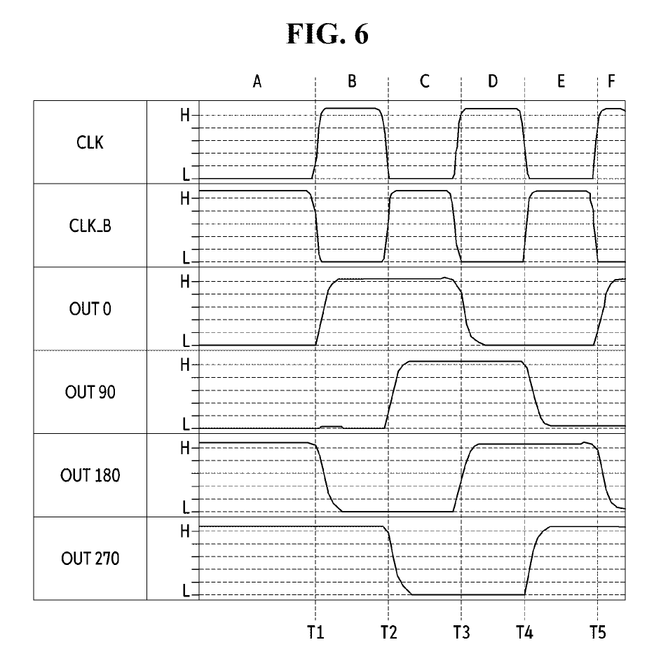

FIG. 6 is a timing diagram for illustrating an operation of a circuit according to FIGS. 4, 5, 7 and 8 are circuit diagrams for illustrating an operation of a circuit according to FIGS. 4 and 5.

Hereinafter, the operation of the clock divider circuit will be described with reference to FIGS. 6-8.

The first to fourth tri-state inverters 400, 500, 600, and 700 may be controlled based on the differential signal including the first input clock CLK and the second input clock CLK_B. The first input clock CLK and the second input clock CLK_B may have inverted logic levels relative to each other.

Referring to FIG. 6, in an initialized state A, each of the first to fourth outputs OUT0, OUT90, OUT180, and OUT270 may be initialized to a specific logic level. In the present disclosure, the first output OUT0 and the second output OUT90 are initialized to the logic low level LOW, and the third output OUT180 and the fourth output OUT270 are initialized to the logic high level HIGH. However, the present disclosure is not limited thereto.

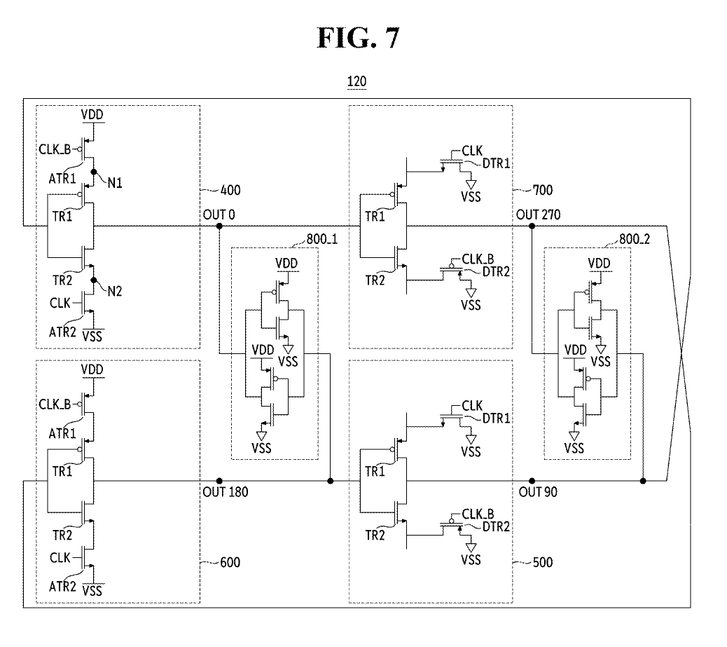

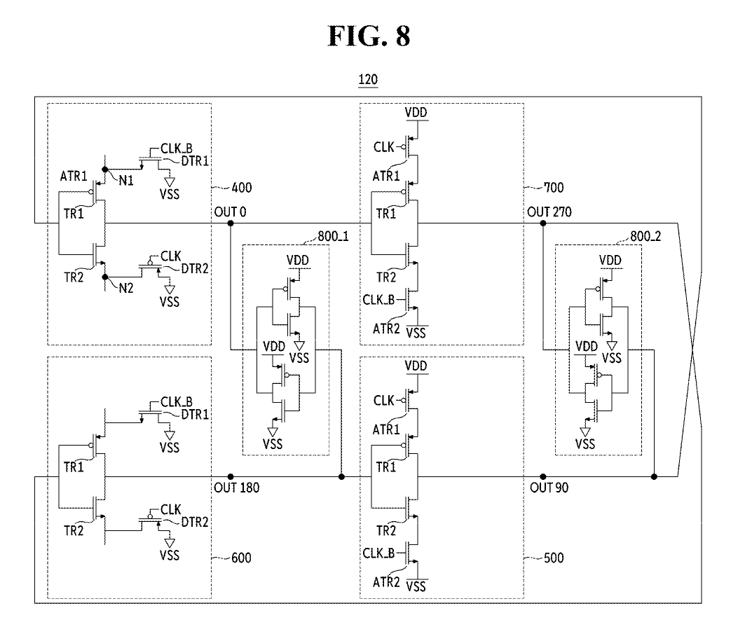

FIG. 7 illustrates an operation when the first input clock CLK is at the logic high level HIGH and the second input clock CLK_B is at the logic low level LOW. FIG. 8 illustrates an operation when the first input clock CLK is at the logic low level LOW and the second input clock CLK_B is at the logic high level HIGH.

Referring to FIG. 6, at a first time point T1, the logic level of the first input clock CLK and the second input CLK_B may be inverted to become a first state B. In the first state B, the first input clock CLK may be at the logic high level HIGH, and the second input clock CLK_B may be at the logic low level LOW.

Referring to FIGS. 6 and 7, when the first input clock CLK is at the logic high level HIGH, the first tri-state inverter 400 and the third tri-state inverter 600 may be activated, and the second tri-state inverter 500 and the fourth tri-state inverter 700 may be brought into a floated state. The second output OUT90 and the fourth output OUT270 may be maintained at the logic value of the initialized state A by the second latch 800_2. The first output OUT0 may be at a logic high level HIGH obtained by inverting the logic level of the second output OUT90 by the first tri-state inverter 400. The third output OUT180 may be at a logic low level LOW obtained by inverting the logic level of the fourth output OUT270 by the third tri-state inverter 600.

Referring to FIG. 6, at a second time point T2, the logic level of the input clock CLK_IN may be inverted to become a second state C. In the second state C, the first input clock CLK may be at the logic low level LOW, and the second input clock CLK_B may be at the logic high level HIGH.

Referring to FIGS. 6 and 8, when the second input clock CLK_B has the logic high level HIGH, the second and fourth tri-state inverters 500 and 700 may be activated, and the first and third tri-state inverters 400 and 600 may be brought into a floated state. The logic value of the first state B of the first output OUT0 and the third output OUT180 may be maintained by the first latch 800_1. The second output OUT90 may be at a logic high level HIGH obtained by inverting the logic level of the third output OUT180 by the second tri-state inverter 500. The fourth output OUT270 may be at a logic low level LOW obtained by inverting the logic level of the first output OUT0 by the fourth tri-state inverter 700.

Referring to FIG. 6, at a third time point T3, the logic level of the first input clock CLK and the second input CLK_B may be inverted to become a third state D. In the third state D, the first input clock CLK may be at the logic high level HIGH, and the second input clock CLK_B may be at the logic low level LOW.

Referring to FIGS. 6 and 7, when the first input clock CLK is at the logic high level HIGH, the first tri-state inverter 400 and the third tri-state inverter 600 may be activated, and the second tri-state inverter 500 and the fourth tri-state inverter 700 may be brought into a floated state. The second output OUT90 and the fourth output OUT270 may be maintained at the logic value of the initialized state A by the second latch 800_2. The first output OUT0 may be at a logic low level LOW obtained by inverting the logic level of the second output OUT90 by the first tri-state inverter 400. The third output OUT180 may be at a logic high level HIGH obtained by inverting the logic level of the fourth output OUT270 by the third tri-state inverter 600.

Referring to FIG. 6, at a fourth time point T4, the logic level of the first input clock CLK and the second input CLK_B may be inverted to become a fourth state E. In the fourth state E, the first input clock CLK may be at the logic low level LOW, and the second input clock CLK_B may be at the logic high level HIGH.

Referring to FIGS. 6 and 8, when the second input clock CLK_B has the logic high level HIGH, the second and fourth tri-state inverters 500 and 700 may be activated, and the first and third tri-state inverters 400 and 600 may be brought into a floated state. The logic value of the third state D of the first output OUT0 and the third output OUT180 may be maintained by the first latch 800_1. The second output OUT90 may be at a logic low level LOW obtained by inverting the logic level of the third output OUT180 by the second tri-state inverter 500. The fourth output OUT270 may be at a logic high level HIGH obtained by inverting the logic level of the first output OUT0 by the fourth tri-state inverter 700.

The logic values of the first to fourth outputs OUT0, OUT90, OUT180, and OUT270 in the fourth state E may be the same as the logic values of the first to fourth outputs OUT0, OUT90, OUT180, and OUT270 in the initialized state A.

Referring to FIG. 6, at a fifth time point T5, the logic level of the first input clock CLK and the second input CLK_B may be inverted to become a fifth state F. The logic values of the first to fourth outputs OUT0, OUT90, OUT180, and OUT270 in the fifth state F may be the same as the logic values of the first to fourth outputs OUT0, OUT90, OUT180, and OUT270 in the first state B.

Referring to FIGS. 7 and 8, charges may be accumulated in the first node N1 or the second node N2. When the voltage generated by the charges accumulated in the first node N1 or the second node N2 is higher than the ground voltage VSS, the charges of the ground voltage VSS node may not migrate to the first node N1 or the second node N2. When the voltage generated by the charges accumulated in the first node N1 or the second node N2 is lower than the ground voltage VSS (that is, when the first node N1 or the second node N2 has a large amount of charges), the charges of the first node N1 or the second node N2 may migrate to the ground voltage VSS node, and accordingly, the voltage of the first node N1 or the second node N2 may increase.

In some implementations, when the tri-state inverter is brought into a floated state, the discharge transistor of the tri-state inverter may be activated. When the tri-state inverter is activated, the discharge transistor of the tri-state inverter may be brought into a floated state.

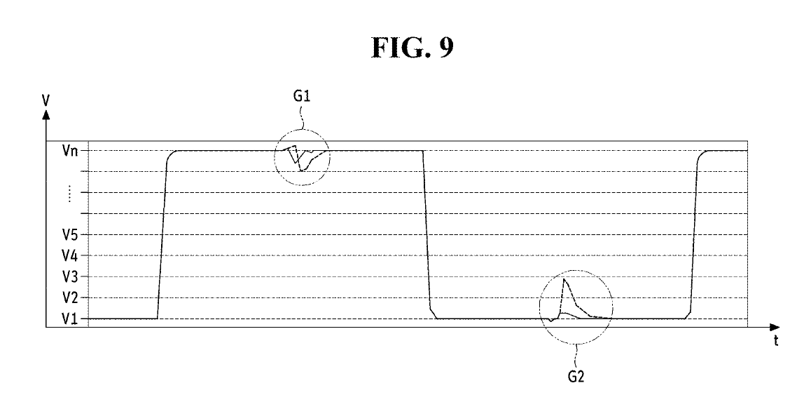

FIG. 9 is a signal analysis diagram for illustrating an effect according to the use of the circuit illustrated in FIGS. 4 and 5.

FIG. 9 is a signal analysis diagram illustrating a voltage V measured over time t at the first output OUT0 of FIG. 5. Referring to FIGS. 5 and 9, a voltage may be changed according to charge sharing between the second node N2 and the first output OUT0 node, and thus, a first glitch G1 may occur. In addition, the voltage V may be changed according to the charge sharing between the first node N1 and the first output OUT0 node, and thus a second glitch G2 may be generated.

In the present disclosure, the first glitch G1 and the second glitch G2 occurring at the first output OUT0 are described below by way of example. However, it should be understood that the following description is substantially equally applied to each of the second to fourth outputs OUT90, OUT180, and OUT270.

Referring to FIGS. 7-9, when the second output OUT90 has the logic low level LOW and the first tri-state inverter 400 is activated, the measurement voltage of the first output OUT0 may be Vn. When the logic level of the input clock CLK_IN is inverted, the second tri-state inverter 500 is activated and the first tri-state inverter 400 is brought into a floated state, so that a logic level of the second output OUT90 becomes the logic high level HIGH and the logic value of the first output OUT0 is maintained. As the logic level of the second output OUT90 becomes the logic high level HIGH, the second transistor TR2 is activated, and the accumulated charges of the second node N2 may migrate to the first output OUT0 node. As the charge of the second node N2 migrates to the first output OUT0 node, the first glitch G1 may occur in the first output OUT0.

The first glitch G1 may be suppressed by the second discharge transistor DTR2. The second discharge transistor DTR2 may be activated when the first tri-state inverter 400 is brought into a floated state. When the second discharge transistor DTR2 is activated, electrons accumulated in the second node N2 may migrate to the ground voltage VSS node. In this case, since a rate at which electrons accumulated in the second node N2 diffuse to the ground voltage VSS node connected to the second discharge transistor DTR2 is higher than a rate at which electrons accumulated in the second node N2 diffuse to the first output OUT0 node, the migration of charges to the first output OUT0 node may be reduced, and thus the first glitch G1 may be suppressed. In FIG. 9, a dotted line of the first glitch G1 refers to a voltage measurement result of the first output OUT0 node of the clock divider circuit without the second discharge transistor DTR2, and a solid line thereof refers to a voltage measurement result of the first output OUT0 of the clock divider circuit with the second discharge transistor DTR2.

Continuously referring to FIGS. 7-9, when the second output OUT90 has the logic high level HIGH and the first tri-state inverter 400 is activated, the measurement voltage of the first output OUT0 may be V1. When the logic level of the input clock CLK_IN is inverted, the second tri-state inverter 500 is activated and the first tri-state inverter 400 is brought into a floated state, so that the logic level of the second output OUT90 becomes the logic low level LOW and the logic value of the first output OUT0 is maintained. As the logic level of the second output OUT90 becomes the logic low level LOW, the first transistor TR1 is activated, and the accumulated charges of the first node may migrate to the first output OUT0 node. As the charge of the first node N1 migrates to the first output OUT0 node, the second glitch G2 may occur in the first output OUT0.

The second glitch G2 may be suppressed by the first discharge transistor DTR1. The first discharge transistor DTR1 may be activated when the first tri-state inverter 400 is brought into a floated state. When the first discharge transistor DTR1 is activated, electrons accumulated in the first node N1 may migrate to the ground voltage VSS node. In this case, since a rate at which the electrons accumulated in the first node N1 diffuse to the ground voltage VSS node connected to the first discharge transistor DTR1 is higher than the rate at which the electrons accumulated in the first node N1 diffuse to the first output OUT0 node, the charge migration to the first output OUT0 node may be reduced, and thus the second glitch G2 may be suppressed. In FIG. 9, the dotted line of the second glitch G2 refers to a voltage measurement result of the first output OUT0 node of the clock divider circuit without the first discharge transistor DTR1, and the solid line thereof refers to a voltage measurement result of the first output OUT0 node of the clock divider circuit with the second discharge transistor DTR2.

Each of the first to fourth outputs OUT0, OUT90, OUT180, and OUT270 in the storage device may be transmitted to another circuit via a buffer outside the clock divider circuit. When there is a glitch in the signal passing through the buffer, a logic error may occur as the signal passes through the buffer. For example, the second glitch G2 of FIG. 9 occurs. Thus, as the signal measured as having V2 to V3 passes through the buffer, the output value of the buffer may be recognized as the logic high level HIGH rather than the logic low level LOW. The discharge transistors DTR1 and DTR2 of the present disclosure may prevent the charge sharing by removing the accumulated charges, thereby reducing the glitch.

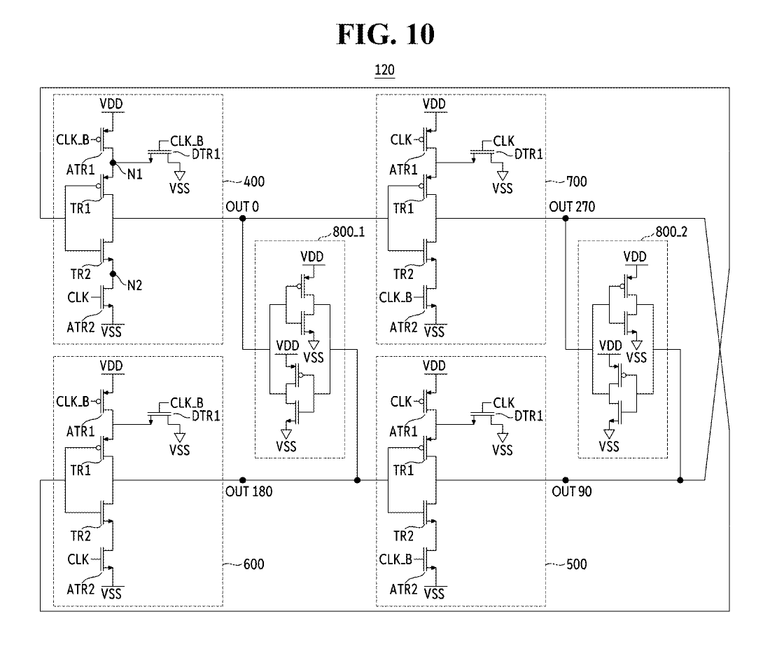

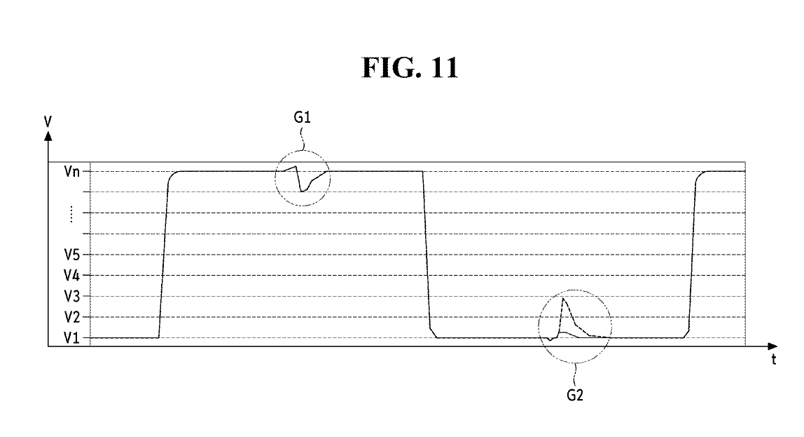

Next, the clock divider circuit according to some implementations will be described with reference to FIGS. 10 and 11. Hereinafter, differences from the above-described implementation will be mainly described.

FIG. 10 is a circuit diagram illustrating a clock divider circuit according to some implementations.

Referring to FIG. 10, each of the first to fourth tri-state inverters 400, 500, 600, and 700 include a first discharge transistor DTR1. One end of the first discharge transistor DTR1 may be connected to the first node N1, and the other end thereof may be connected to the ground voltage VSS node. The first discharge transistor DTR1 may be gated based on the second input clock CLK_B to remove the accumulated charge of the first node N1.

FIG. 11 is a signal analysis diagram for illustrating an effect of using the circuit illustrated in FIG. 10.

FIG. 11 illustrates a voltage measured at a first output OUT0 node. In a state in which the first output OUT0 is at the logic high level HIGH, the first tri-state inverter 400 may be brought into a floated state to generate the first glitch G1.

The first tri-state inverter 400 may be brought into a floated state in a state in which the first output is at the logic low level LOW, and thus, the second glitch G2 may be generated. The second glitch G2 may be suppressed by the first discharge transistor DTR1. The first discharge transistor DTR1 may be activated when the logic level of the second input clock CLK_B becomes the logic high level HIGH such that the first tri-state inverter 400 is brought into a floated state. The activated first discharge transistor DTR1 may remove the charges accumulated in the first node N1 to suppress the second glitch G2.

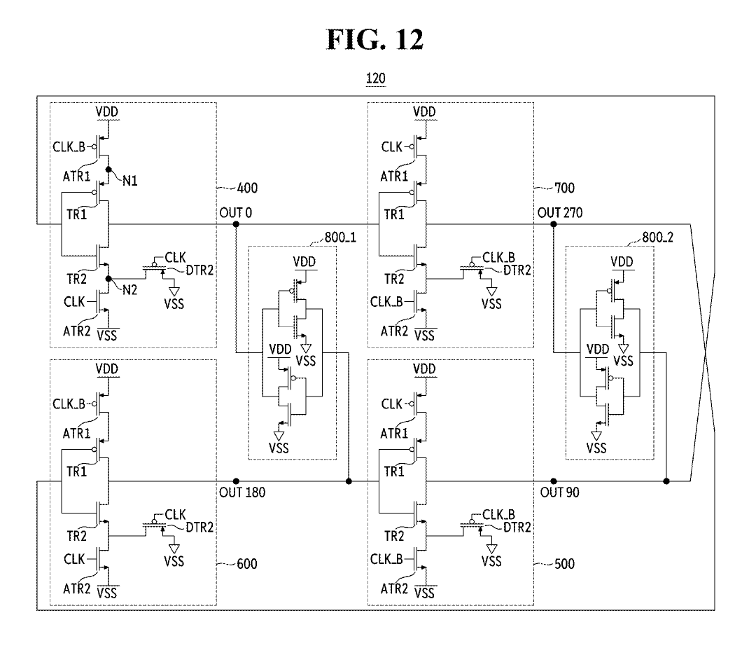

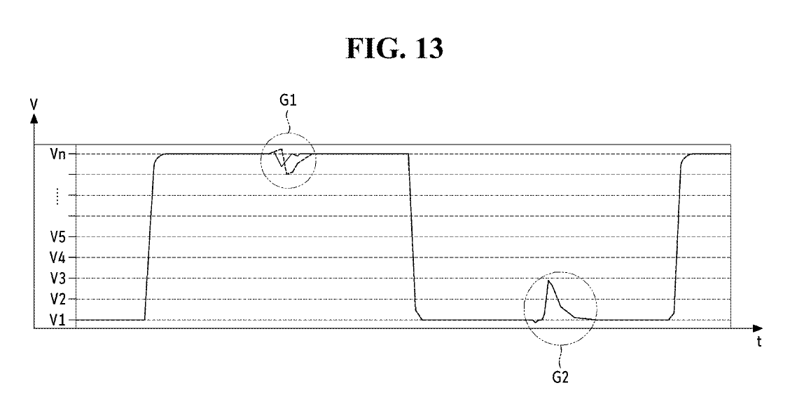

Next, the clock divider circuit according to some implementations will be described with reference to FIGS. 12 and 13. Hereinafter, differences from the above-described implementation will be mainly described.

FIG. 12 is a circuit diagram illustrating a clock divider circuit according to some implementations. Each of the first to fourth tri-state inverters 400, 500, 600, and 700 include a second discharge transistor DTR2. One end of the second discharge transistor DTR2 may be connected to the second node N2, and the other end thereof may be connected to the ground voltage VSS node. The second discharge transistor DTR2 may be gated based on the first input clock CLK to remove charges accumulated in the second node N2.

FIG. 13 is a signal analysis diagram for illustrating an effect of using the circuit illustrated in FIG. 12.

FIG. 13 illustrates a voltage measured at a first output OUT0 node. In a state in which the first output OUT0 is at the logic high level HIGH, the first tri-state inverter 400 may be brought into a floated state to generate the first glitch G1. The first glitch G1 may be suppressed by the second discharge transistor DTR2. The second discharge transistor DTR2 may be activated when the logic level of the first input clock CLK becomes the logic low level LOW such that the first tri-state inverter 400 is brought into a floated state. The activated second discharge transistor DTR2 may remove charges accumulated in the second node N2 to suppress the first glitch G1.

Referring to FIG. 13, the first tri-state inverter 400 may be brought into a floated state in a state in which the first output OUT1 is at the logic low level LOW, and thus, the second glitch G2 may occur.

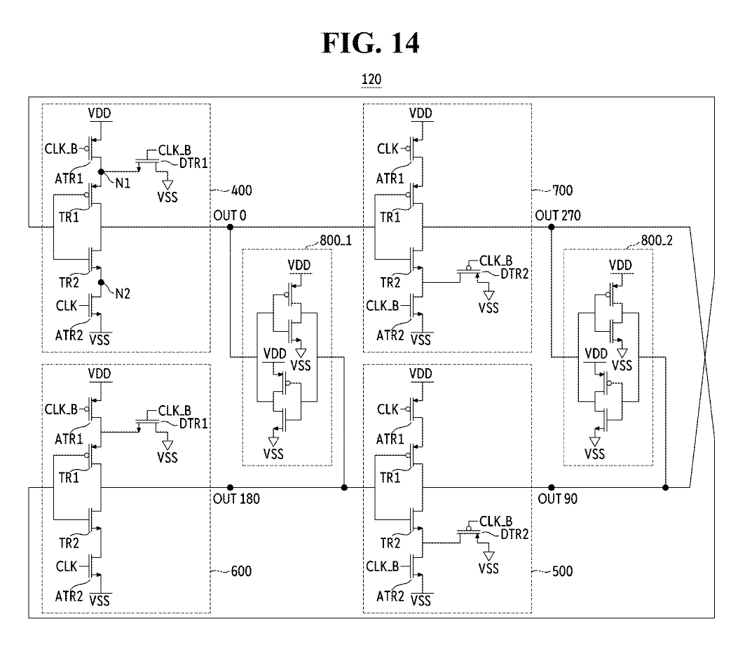

Next, the clock divider circuit according to some implementations will be described with reference to FIG. 14. Hereinafter, differences from the above-described implementation will be mainly described.

FIG. 14 is a circuit diagram illustrating a clock divider circuit according to some implementations.

Referring to FIG. 14, each of the first to fourth tri-state inverters 400, 500, 600, and 700 may include at least one of a first discharge transistor DTR1 and a second discharge transistor DTR2. In some implementations, each of the first and third tri-state inverters 400 and 60 may include the first discharge transistor DTR1 connected to the first node N1, and each of the second and fourth tri-state inverters 500 and 700 may include the second discharge transistor DTR2 connected to the second node N2.

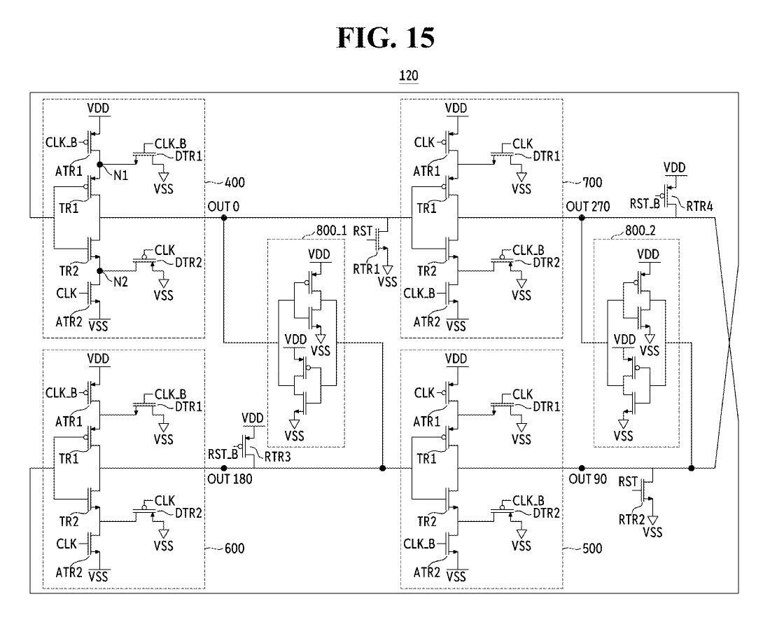

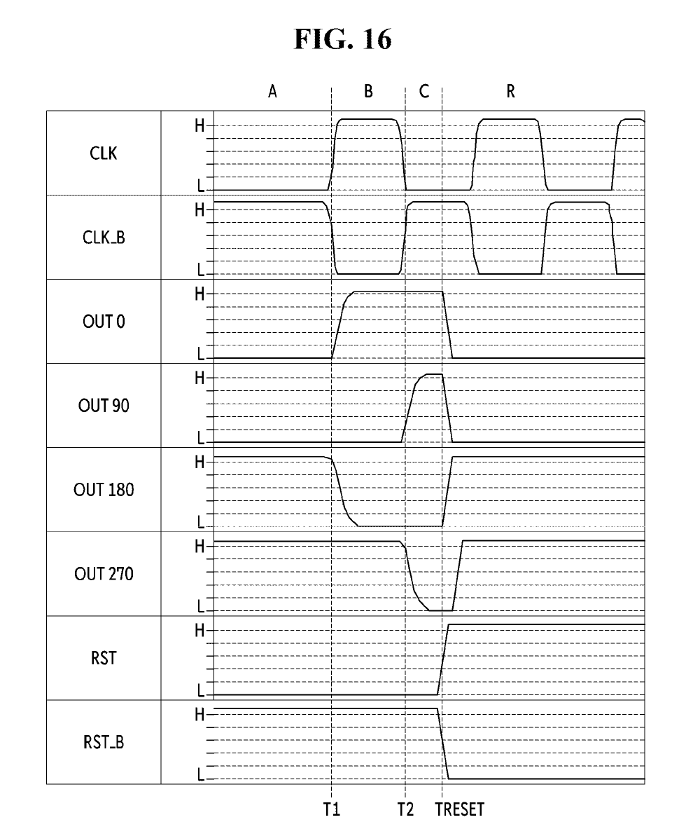

Next, the clock divider circuit according to some implementations will be described with reference to FIGS. 15 and 16. Hereinafter, differences from the above-described implementation will be mainly described.

FIG. 15 is a circuit diagram illustrating a clock divider circuit according to some implementations.

Referring to FIG. 15, the clock divider circuit CDC may include first to fourth reset transistors RTR1, RTR2, RTR3, and RTR4. Each of the first to fourth reset transistors RTR1, RTR2, RTR3, and RTR4 may be controlled based on a reset signal RST. The reset signal may include a first reset signal RST and a second reset signal RST_B as a differential signal. In this case, the second reset signal RST_B may be a signal of a logic level obtained by inverting the logic level of the first reset signal RST.

One end of the first reset transistor RTR1 may be connected to the first output OUT0 node, and the other end thereof may be connected to the ground voltage VSS node. The first reset transistor RTR1 may be gated based on the first reset signal RST so that the logic level of the first output OUT0 becomes the logic low level LOW. One end of the second reset transistor RTR2 may be connected to the node of the second output OUT90, and the other end thereof may be connected to the ground voltage VSS node. The second reset transistor RTR2 may be gated based on the first reset signal RST so that the second output OUT90 may be at the logic low level LOW. One end of the third reset transistor RTR3 may be connected to the node of the third output OUT180, and the other end thereof may be connected to the driving voltage VDD node. The third reset transistor RTR3 may be gated based on the second reset signal RST_B to allow the third output to have the logic high level HIGH. One end of the fourth reset transistor RTR4 may be connected to the node of the fourth output OUT270, and the other end thereof may be connected to the driving voltage VDD node. The fourth reset transistor RTR4 may be gated based on the second reset signal RST_B so that the fourth output OUT270 may be at the logic high level HIGH.

FIG. 16 is a timing diagram for illustrating an effect of using the circuit illustrated in FIG. 15.

Referring to FIG. 16, after a reset time point TRESET, the clock divider circuit may become the initialized state A. In a reset state R, the logic level of the first reset signal RST may become the logic high level HIGH, and the logic level of the second reset signal RST_B may become the logic low level LOW. The logic level of each of the first and second outputs OUT0 and OUT90 may become the logic low level LOW as the logic level of the first reset signal RST becomes the logic high level HIGH. The logic level of each of the third and fourth outputs OUT180 and OUT270 may become the logic high level HIGH as the logic level of the second reset signal RST_B becomes the logic low level LOW.

In the reset state R, each of the first to fourth outputs OUT0, OUT90, OUT180, and OUT270 may be initialized to have the same logic level as that of each of the first to fourth outputs OUT0, OUT90, OUT180, and OUT270 of the initialized state A. In the present disclosure, an example has been described in which the first and second outputs OUT0 and OUT90 are at the logic low level LOW and the third and fourth outputs OUT180 and OUT270 are at the logic high level HIGH in the initialized state A. However, the present disclosure is not limited thereto, and the first to fourth outputs may have logic levels different from those in the above example.

Next, the clock divider circuit according to some implementations will be described with reference to FIG. 7. Hereinafter, differences from the above-described implementation will be mainly described.

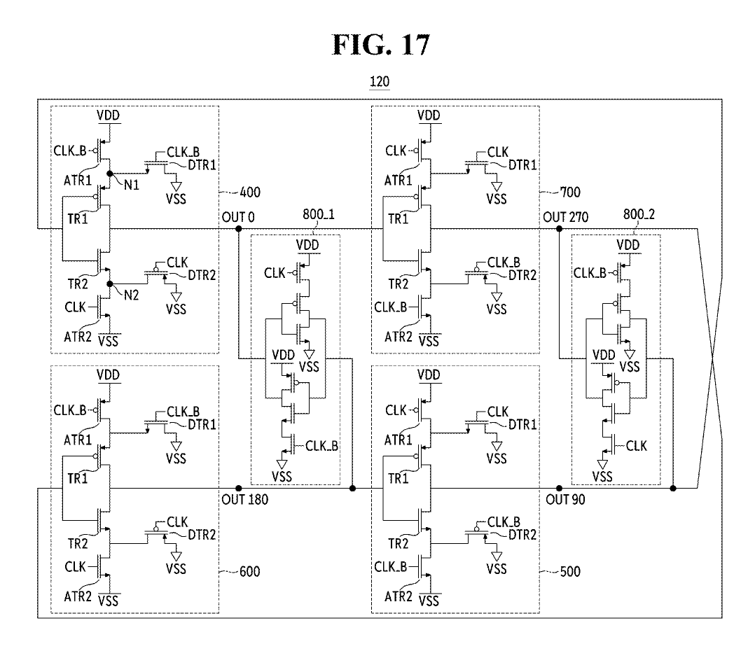

FIG. 17 is a circuit diagram illustrating a clock divider circuit according to some implementations.

Referring to FIG. 17, the first latch 800_1 may be activated when the first input clock CLK is at the logic low level LOW. When each of the first tri-state inverter 400 and the third tri-state inverter 600 is brought into the floated state, the first latch 800_1 may maintain the logic levels of the first output OUT0 and the third output OUT180. The second latch 800_2 may be activated when the first input clock CLK is at the logic high level HIGH. When each of the second tri-state inverter 500 and the fourth tri-state inverter 700 is brough into the floated state, the second latch 800_2 may maintain the logic levels of the second output OUT90 and the fourth output OUT270.

The first latch 800_1 may be brought into a floated state when the first input clock CLK is at the logic high level HIGH. In this case, the first output OUT0 and the third output OUT180 may have logic levels that are inverted relative to the logic level of the second output OUT90 and the logic level of the fourth output OUT270, respectively. The second latch 800_2 may be brought into a floated state when the first input clock CLK is at the logic low level LOW. In this case, the second output OUT90 and the fourth output OUT270 may have logic levels inverted relative to the logic levels of the third output OUT180 and the first output OUT0, respectively.

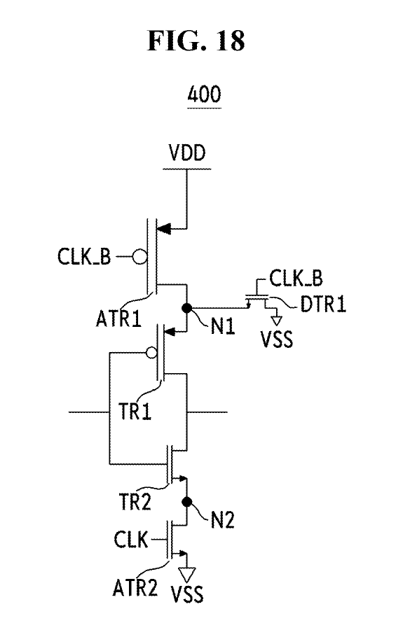

FIG. 18 is a circuit diagram illustrating a tri-state inverter of a clock divider circuit according to some implementations.

Referring to FIG. 18, the first active transistor ATR1, the first transistor TR1, and the first discharge transistor DTR1 of the first tri-state inverter 400 may have different sizes. In the present disclosure, "different sizes" means that the widths among the widths and lengths of the transistors are different from each other. However, the different sizes of the transistors does not imply that "the lengths of the transistors are equal to each other". It should be understood that the size of the transistor is irrelevant to the length thereof in the present disclosure. For example, even when the size of the second transistor TR2 is greater than the size of the first transistor TR1, the length of the first transistor TR1 may be larger than the length of the second transistor TR2.

In some implementations, the size of the first active transistor ATR1 may be greater than the size of the first transistor TR1. The first active transistor ATR1 may be directly connected to the power supply so as to provide driving power to the first transistor TR1. The driving power is transmitted to the first transistor TR1 via the first active transistor ATR1 in a form of a drift current, and the drift current increases in direct proportion to the width of the transistor. As the magnitude of the current transmitted to the first transistor TR1 increases, the operating speed of the first inverter INV1 including the first transistor TR1 may increase, and the clock divider circuit may operate at a higher speed. Accordingly, when the width of the first active transistor TR1 increases, the channel of the current flowing to the first transistor TR1 increases such that a relatively large current may flow, and accordingly, the clock divider circuit may operate at a high speed.

The first discharge transistor DTR1 is connected to the first node N1 where charge accumulation occurs, and is configured to prevent the charge from being shared with the first output node OUT0. The electric charge accumulated in the first node N1 migrates to the ground voltage VSS node via the first discharge transistor DTR1. The charges accumulated in the first node N1 mainly diffuse to migrate to the ground voltage VSS node. In this case, since the amount of accumulated charges is not large, the transistors may be manufactured such that the width of the first discharge transistor DTR1 is smaller than the width of the first transistor TR1. When the size of the first discharge transistor DTR1 is reduced, the overall size of the first tri-state inverter 400 may be reduced.

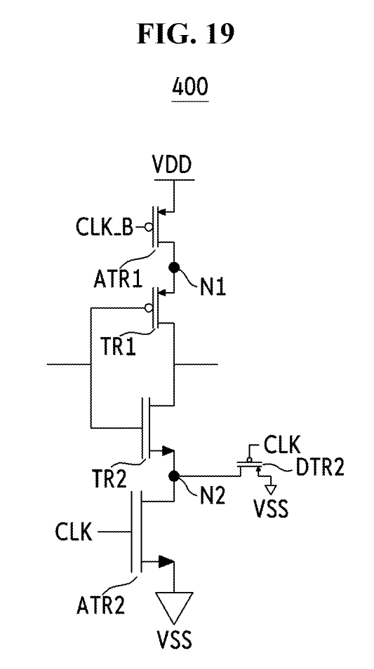

FIG. 19 is a circuit diagram illustrating a tri-state inverter of a clock divider circuit according to some implementations.

Referring to FIG. 19, the second active transistor ATR2, the second transistor TR2, and the second discharge transistor DTR2 may have different sizes. In some implementations, the size of the second active transistor ATR2 may be greater than the size of the second transistor TR2. As the size of the second active transistor ATR2 increases, the clock divider circuit may operate at a relatively high speed.

The size of the second discharge transistor DTR2 may be smaller than the size of the second transistor TR2. As the size of the second discharge transistor DTR2 decreases, the overall size of the first tri-state inverter INV1 may decrease.

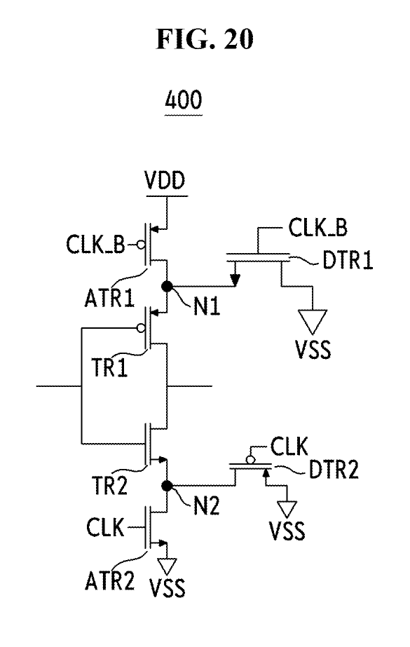

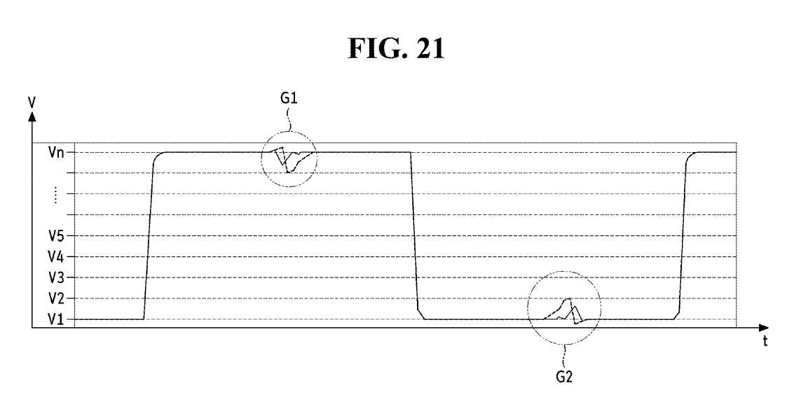

FIG. 20 is a circuit diagram illustrating a tri-state inverter of a clock divider circuit according to some implementations. FIG. 21 is a signal analysis diagram for illustrating an effect of using the circuit illustrated in FIG. 20.

Referring to FIGS. 20 and 21, the size of the first discharge transistor DTR1 of the first tri-state inverter 400 may be different from the size of the second discharge transistor DTR2. The size of each of the first discharge transistor DTR1 and the second discharge transistor DTR2 may be adjusted to minimize a difference between the first glitch G1 caused by the charge accumulated at the second node N2 and the second glitch G2 caused by the charge accumulated at the first node N1.

In some implementations, the size of the first discharge transistor DTR1 may be greater than the size of the second discharge transistor DTR2. In order to suppress the second glitch G2 more effectively than the first glitch G1, the size of the first discharge transistor DTR1 may be set to be larger than the size of the second discharge transistor DTR2.

In some other implementations, the size of the first discharge transistor DTR1 may be smaller than the size of the second discharge transistor DTR2. For example, the first discharge transistor DTR1 which is embodied as an N-type metal-oxide-semiconductor (NMOS) may be set to have a smaller size so as to secure the same performance as that of the second discharge transistor DTR2 which is embodied as a P-type metal-oxide-semiconductor (PMOS).

Although FIGS. 18-21 have been described based on the first tri-state inverter 400 by way of example, implementations according to the technical idea of the present disclosure are not limited thereto, and the above description may be equally applied to each of the second to fourth tri-state inverters 700.

The configuration as described with reference to FIGS. 18-20 may be employed as the configuration of the tri-state inverter of the above-described implementations.

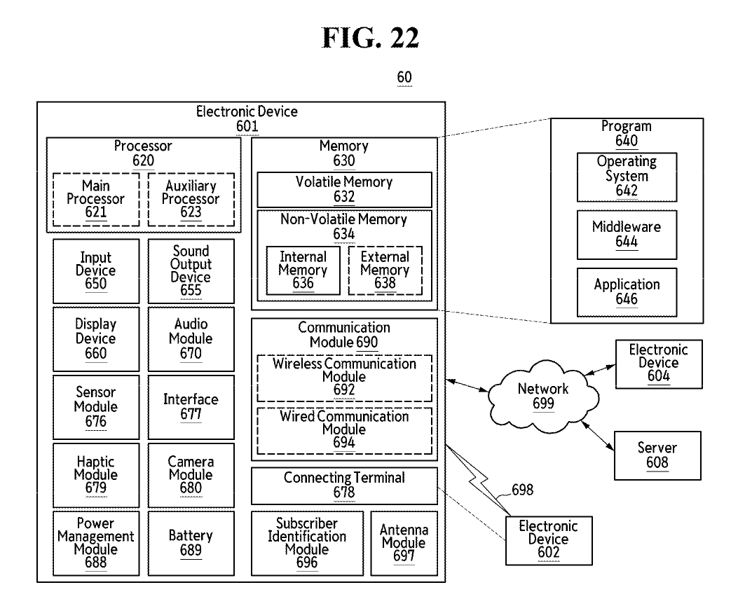

FIG. 22 is a block diagram for illustrating an electronic device including a storage device to which a clock divider circuit according to some implementations is applied.

Referring to FIG. 22, an electronic device 601 in a network environment may communicate with an electronic device 602 over a first network 698, for example, a short-range wireless communication network, or may communicate with an electronic device 604 or a server 608 over a second network 699 such as a long-range wireless communication network. In some implementations, the electronic device 601 may be, for example, a notebook computer, a laptop computer, a portable mobile terminal, etc. However, implementations are not limited thereto.

The electronic device 601 may communicate with the electronic device 604 via the server 608. The electronic device 601 may include a processor 620, a memory 630, an input device 650, a sound output device 655, an image display device 660, an audio module 670, a sensor module 676, an interface 677, a haptic module 679, a camera module 680, a power management module 688, a battery 689, a communication module 690, a subscriber identification module (SIM) 696 or an antenna module 697.

In some implementations, for example, at least one of components such as the display device 660 or the camera module 680 may be omitted from the electronic device 601, or at least one further component may be added to the electronic device.

In some implementations, some of the components may be implemented as a single integrated circuit (IC). For example, the sensor module 676 such as a fingerprint sensor, an iris sensor, and an illuminance sensor may be embedded in an image display device such as a display.

The processor 620 may execute software (for example, a program 640) that controls other components of at least one electronic device 601 such as a hardware or software component connected to the processor 620 to perform various data processing and computations.

Under data processing or at least some of computations, the processor 620 may load a command or data received from another component such as the sensor module 676 or the communication module 690 into a volatile memory 632, and process the command or data stored in the volatile memory 632, and store resulting data in a non-volatile memory 634.

The processor 620 may include, for example, a main processor 621 such as a central processing unit (CPU) or a smartphone application processor (AP) and an auxiliary processor 623 operating independently of the main processor 621 or in connection with the main processor 621.

The auxiliary processor 623 may include, for example, a graphic processing unit (GPU), an image signal processor (ISP), a sensor hub processor, or a communication processor (CP), etc. The graphic processing unit may act as an accelerator for processing the original model or the pruned model as described above.

In some implementations, the auxiliary processor 623 may be configured to consume less power or than that of the main processor 621 or perform certain functions. The auxiliary processor 623 may be separate from the main processor 621 or implemented as a portion thereof.

The auxiliary processor 623 may control at least some of functions or states related to at least one of the components of the electronic device 601 on behalf of the main processor 621 while the main processor 621 is inactive, or together with the main processor 621 while the main processor 621 is active.

The memory 630 may store therein various data used in at least one component of the electronic device 601. The various data may include, for example, software such as the program 640, and input data and output data for related commands. The memory 630 may include the volatile memory 632 and the non-volatile memory 634.

The program 640 may be stored as software in the memory 630, and may include, for example, an operating system (OS) 642, middleware 644, or an application 646.

The input device 650 may receive a command or data to be used for other components of the electronic device 601 from a device external to the electronic device 601. The input device 650 may include, for example, a microphone, mouse, or keyboard.

The sound output device 655 may output a sound signal out of the electronic device 601. The sound output device 655 may include, for example, a speaker or a receiver. The speaker may be used for general purpose of playing multimedia or recording a sound. The receiver may be used to receive an incoming call.

The image display device 660 may visually provide information out of the electronic device 601. The image display device may include, for example, a display, a hologram device, or a projector, and a control circuit for controlling a corresponding one of the display, the hologram device, or the projector.

In some implementations, the image display device 660 may include a touch circuit configured to detect a touch, or a sensor circuit configured to measure intensity of a force induced by the touch, for example, a pressure sensor.

The audio module 670 may convert a sound into an electrical signal or vice versa. In some implementations, the audio module 670 may obtain a sound via the input device 650 or output the sound via the sound output device 605 or a headphone of an external electronic device 602 directly or wirelessly connected to the electronic device 601.

The sensor module 676 may detect, for example, an operating state of the electronic device 601 such as output or temperature, or an environmental state external to the electronic device 601 such as a user's state, and may generate an electrical signal or data corresponding to the detected state. The sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support at least one prescribed protocol to be used by the electronic device 601 directly or wirelessly connected to the external device 602. In some implementations, the interface 677 may include, for example, a high definition multimedia interface (HDMI), an universal serial bus (USB) interface, a secure digital (SD) card interface, or a voice interface.

A connection terminal 678 may include a connector through which the electronic device 601 may be physically connected to the external electronic device 602. In some implementations, the connection terminal 678 may include, for example, an HDMI connector, a USB connector, an SD card connector, or a voice connector such as a headphone connector.

The haptic module 679 may convert an electrical signal into a mechanical stimulus, for example, vibration or motion, which may be recognized by a user via a haptic sensation or a kinesthetic sensation. In some implementations, the haptic module 679 may include, for example, a motor, a piezoelectric element, or an electrical stimulator.

The camera module 680 may capture still images or moving images. In some implementations, the camera module 680 may include at least one lens, an image sensor, an image signal processor, or a flash.

The battery 689 may supply power to at least one component of the electronic device 601. According to some implementations, the battery 689 may include, for example, a primary battery that is not rechargeable, a secondary battery that is rechargeable, or a fuel cell.

The power management module 688 may manage power supplied to the electronic device 601. The power management module may be implemented, for example, as at least a portion of a power management integrated circuit (PMIC).

The communication module 690 supports establishment of a direct communication channel or a wireless communication channel between the electronic device 601 and an external electronic device such as, for example, the electronic device 602, the electronic device 604, or the server 608, and communicates therewith via the established communication channel.

The communication module 690 may operate independently of the processor 620, and may include at least one communication processor supporting direct communication or wireless communication.

In some implementations, the communication module 690 may include, for example, a wireless communication module 692 such as a mobile communication (cellular communication module), a short-range wireless communication module, or a global navigation satellite system (GNSS) communication module, or a wired communication module 690 such as a local area network (LAN) communication module, or a power line communication (PLC) module.

A corresponding communication module among these communication modules may communicate with an external electronic device over the first network 698 such as, for example, blue-tooth Bluetooth™, Wi-Fi (wireless-fidelity), direct or IrDA (standard of the Infrared Data Association) or the second network 699 such as, for example, the mobile communication network, the Internet, and the long-range communication network.

These various types of communication modules may be implemented, for example, as a single component or as a plurality of components separated from each other. The wireless communication module 692 may use, for example, subscriber information such as international mobile subscriber identity (IMSI) stored in the user identification module 696 to identify and authenticate the electronic device 601 in a communication network such as the first network 698 or the second network 699.

The antenna module 697 may transmit or receive a signal or power to or from a device external to the electronic device 601. In some implementations, the antenna module 697 may include at least one antenna. Thus, at least one antenna suitable for a communication scheme used in a communication network such as the first network 698 or the second network 699 may be selected by the communication module 690. Then, the signal or power may be transmitted or received between the communication module and the external electronic device via the selected at least one antenna.

At least some of the aforementioned components may be interconnected to each other, and may communicate a signal therebetween in an inter-peripheral communication scheme such as, for example, a bus, a general purpose input and output (GPIO), a serial peripheral interface (SPI), or a mobile industry processor interface (MIPI).

In some implementations, the command or data may be transmitted or received between the electronic device 601 and the external electronic device 604 via the server 608 connected to the second network 699. Each of the electronic devices 602 and 604 may be of the same type as or a different type from that of the electronic device 601. All or some of the operations to be executed on the electronic device 601 may be executed on at least one external electronic device 602, 604, or 608. For example, all or some of the operations to be executed on the electronic device 601 may be executed on at least one external electronic device 602, 604, or 608.

For example, when the electronic device 601 is configured to perform a function or service automatically or in response to a request from a user or other device, the electronic device 601 executing the function or service may request at least one external electronic device to perform at least a portion of the function or service instead or in addition to the device 601. At least one external electronic device that has received the request may perform at least a portion of the requested function or service or an additional function or additional service related to the request, and transmit a result of the execution to the electronic device 601. The electronic device 601 provides the result as at least a portion of a response to the request with or without further processing of the result. For this purpose, for example, cloud computing, distributed computing, or client-server computing technologies may be used.

According to some implementations, the memory 630 may include the storage device 30 of FIG. 1. The memory 630 may include a clock divider circuit. The memory 630 may receive a power voltage from, for example, the power management module 688, the battery 689, and the like. The memory 630 may receive, for example, the data clock from the processor 620. The clock divider circuit of the memory 630 may divide the clock signal CLK into the plurality of clock signals based on, for example, the data clock DCLK.

Although implementations of the present disclosure have been described above with reference to the accompanying drawings, the present disclosure may not be limited to implementations and may be implemented in various different forms. Those of ordinary skill in the technical field to which the present disclosure belongs will be able to appreciate that the present disclosure may be implemented in other specific forms without changing the technical idea or essential features of the present disclosure. Therefore, it should be understood that implementations as described above are not restrictive but illustrative in all respects.

In concluding the detailed description, those skilled in the art will appreciate that many variations and modifications may be made to the implementations without substantially departing from the principles of the present disclosure. Therefore, the disclosed implementations of the disclosure are used in a generic and descriptive sense only and not for purposes of limitation.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A clock divider circuit comprising:
four tri-state inverters connected in series and forming a closed circuit, wherein the four tri-state inverters are configured to divide an input clock into a plurality of output clocks; and
a latch configured to
latch an output of a first tri-state inverter of the four tri-state inverters to provide a first latched signal, provide the first latched signal to an input of a second tri-state inverter of the four tri-state inverters, latch an output of a third tri-state inverter of the four tri-state inverters to provide a second latched signal, and provide the second latched signal to an input of a fourth tri-state inverter of the four tri-state inverters,
wherein the first tri-state inverter comprises
a first inverter connected to an input terminal and an output terminal of the first tri-state inverter,
a first active transistor configured to provide a driving voltage to the first inverter based on the input clock,
a second active transistor configured to provide a ground voltage to the first inverter based on the input clock, and
a discharge transistor connected to the first inverter and configured to remove accumulated charges generated by at least one of the first active transistor and the second active transistor.

2. The clock divider circuit of claim 1, wherein the discharge transistor is connected to the first inverter and the first active transistor.

3. The clock divider circuit of claim 2, wherein a width of the discharge transistor is smaller than or equal to a width of the first active transistor.

4. The clock divider circuit of claim 2, wherein the discharge transistor is a first discharge transistor, wherein the first tri-state inverter comprises
a second discharge transistor connected to the first inverter and the second active transistor.

5. The clock divider circuit of claim 4, wherein a width of the first discharge transistor is less than or equal to a width of the first active transistor, and
wherein a width of the second discharge transistor is less than or equal to a width of the second active transistor.

6. The clock divider circuit of claim 4, wherein a width of the first discharge transistor is greater than or equal to a width of the second discharge transistor.

7. The clock divider circuit of claim 1, wherein the discharge transistor is connected to the first inverter and the second active transistor.

8. The clock divider circuit of claim 7, wherein a width of the discharge transistor is less than or equal to a width of the second active transistor.

9. The clock divider circuit of claim 1, wherein a discharge transistor of each of the second tri-state inverter, the third tri-state inverter, and the fourth tri-state inverter is configured to remove accumulated charges generated by the first active transistor or the second active transistor.

10. The clock divider circuit of claim 1, comprising a reset transistor configured to initialize an input of each tri-state inverter of the four tri-state inverters based on a reset signal.

11. A clock divider circuit comprising:
four tri-state inverters connected in series and forming a closed circuit, wherein the four tri-state inverters are configured to divide a first input clock and a second input clock into a plurality of output clocks, wherein logic levels of the first input clock and the second input clock are inverted relative to each other;
a first latch comprising a first input connected to an output of a first tri-state inverter of the four tri-state inverters and to an input of a fourth tri-state inverter of the four tri-state inverters, and comprising a second input connected to an output of a third tri-state inverter of the four tri-state inverters and to an input of a second tri-state inverter of the four tri-state inverters; and
a second latch comprising a third input connected to an output of the fourth tri-state inverter and to an input of the third tri-state inverter, and comprising a fourth input connected to an output of the second tri-state inverter and to an input of the first tri-state inverter,
wherein the first tri-state inverter comprises:
a first transistor and a second transistor configured to invert an input of the first tri-state inverter and output the inverted input;
a first active transistor configured to provide a driving voltage to the first transistor based on the first input clock;
a second active transistor configured to provide a ground voltage to the second transistor based on the second input clock; and
a first discharge transistor connected to the first transistor and to the first active transistor, and configured to provide the ground voltage to the first transistor and to the first active transistor based on the second input clock.

12. The clock divider circuit of claim 11, wherein the first tri-state inverter comprises a second discharge transistor connected to the second transistor and to the second active transistor, and configured to provide the ground voltage to the second transistor and to the second active transistor based on the first input clock.

13. The clock divider circuit of claim 12, wherein a width of the first discharge transistor is greater than or equal to a width of the second discharge transistor.

14. The clock divider circuit of claim 11, wherein the first tri-state inverter and the third tri-state inverter are configured to be activated based on the first input clock having a logic high level,
wherein the first tri-state inverter and the third tri-state inverter are configured to be in a float state based on the first input clock having a logic low level,
wherein the second tri-state inverter and the fourth tri-state inverter are configured to be activated based on the first input clock having a logic low level, and
wherein the second tri-state inverter and the fourth tri-state inverter are configured to be in a float state based on the first input clock having a logic high level.

15. The clock divider circuit of claim 11, wherein a width of the first active transistor is greater than or equal to a width of the first transistor,
wherein a width of the first transistor is greater than or equal to a width of the first discharge transistor.

16. A storage system comprising:
a memory device;
a storage controller configured to control the memory device; and
an input/output circuit configured to transmit an external input to the memory device and the storage controller,
wherein the input/output circuit comprises a clock divider circuit configured to divide an input clock into a plurality of output clocks,
wherein the clock divider circuit comprises:
four tri-state inverters connected in series and forming a closed circuit, wherein each tri-state inverter of the four tri-state inverters is configured to divide an input clock into a plurality of output clocks; and
a latch configured to latch an output of a first tri-state inverter of the four tri-state inverters to provide a first latched signal,
provide the first latched signal to an input of a second tri-state inverter of the four tri-state inverters,
latch an output of a third tri-state inverter of the four tri-state inverters to provide a second latched signal, and
provide the second latched signal to an input of a fourth tri-state inverter of the four tri-state inverters,
wherein the first tri-state inverter comprises
a first inverter connected to an input terminal and an output terminal of the first tri-state inverter, and
a first active transistor configured to provide a driving voltage to the first inverter based on the input clock,
a second active transistor configured to provide a ground voltage to the first inverter based on the input clock, and
a discharge transistor connected to the first inverter and configured to remove accumulated charges generated by at least one of the first active transistor and the second active transistor.

17. The storage system of claim 16, wherein the discharge transistor is a first discharge transistor,
wherein the first discharge transistor is connected to the first active transistor.

18. The storage system of claim 17, wherein a width of the first discharge transistor is smaller than or equal to a width of the first active transistor.

19. The storage system of claim 17, wherein the first tri-state inverter comprises a second discharge transistor,
wherein the second discharge transistor is connected to the second active transistor.

20. The storage system of claim 19, wherein a width of the first discharge transistor is greater than or equal to a width of the second discharge transistor.
